(19) United States
(12) Patent Application Publication
(10) Pub. No.: US 2013/0082366 A1
(43) Pub. Date: Apr. 4, 2013

(54) SEMICONDUCTOR PACKAGE AND METHOD OF MANUFACTURING THE SAME

(71) Applicant: Kwang Chun JUNG, Suwon (KR)

(72) Inventor: Kwang Chun JUNG, Suwon (KR)

(73) Assignee: SAMSUNG ELECTRO-MECHANICS CO., LTD.

(21) Appl. No.: 13/325,401

(22) Filed: Dec. 14, 2011

(30) Foreign Application Priority Data
Sep. 30, 2011 (KR) 10-2011-0100123

(51) Int. Cl. H01L 23/552; H01L 21/78

(52) U.S. Cl. 257/659; 438/113; 257/E23.114; 257/E21.599

(57) ABSTRACT

There is provided a semiconductor package including: a substrate having at least one element mounted thereon; a prepreg layer stacked on the substrate to cover the at least one element; a metal shielding layer stacked on the prepreg layer to electrically shield the at least one element; and a via electrode penetrating through the metal shielding layer and the prepreg layer and electrically connected to a ground electrode formed on the substrate.

### CROSS-REFERENCE TO RELATED APPLICATIONS

This application claims the priority of Korean Patent Application No. 10-2011-0100123 filed on Sep. 30, 2011, in the Korean Intellectual Property Office, the disclosure of which is incorporated herein by reference.

### BACKGROUND OF THE INVENTION

1. Field of the Invention

The present invention relates to a semiconductor package and a method of manufacturing the same.

2. Description of the Related Art

In recent years, demand for mobile devices has rapidly increased in the electronic product market. Accordingly, miniaturization and lightening of electronic parts mounted in these products is increasingly being demanded.

In order to achieve the miniaturization and the lightening of these electronic parts, not only a technique for reducing individual sizes thereof, but also a system on chip (SOC) technique for integrating a plurality of individual elements into a single chip or a system in package (SIP) technique for integrating a plurality of individual elements into a single package is required.

In particular, a high frequency semiconductor package dealing with high frequency signals, such as in the case of a mobile TV (DMB or DVB) module or a network module, is required to include various electromagnetic wave shielding structures in order to achieve the miniaturization and realize excellent electro-magnetic interference (EMI) or electro-magnetic susceptibility (EMS) characteristics.

To achieve this, related art devices employ an electromagnetic wave shielding structure having a cover member made of a metal material mounted thereon. However, in this structure, the cover member should be spaced apart from elements by a predetermined distance such that an overall height of a product may be enlarged due to the thickness of the cover member.

Another method in the related art employs a structure in which elements are packaged using a molding product and are then covered with a thin conductive film. However, a molding material of this structure may be vulnerable to moisture, thereby leading to poor moisture resistance.

### SUMMARY OF THE INVENTION

An aspect of the present invention provides a semiconductor package having improved moisture resistance while realizing slimming thereof, and a method of manufacturing the same.

According to an aspect of the present invention, there is provided a semiconductor package including: a substrate having at least one element mounted thereon; a prepreg layer stacked on the substrate to cover the at least one element; a metal shielding layer stacked on the prepreg layer to electrically shield the at least one element; and a via electrode penetrating through the metal shielding layer and the prepreg layer and electrically connected to a ground electrode formed on the substrate.

The via electrode may include a plurality of via electrodes, and the plurality of via electrodes may be spaced apart from each other along edges of the prepreg layer and the metal shielding layer.

According to another aspect of the present invention, there is provided a method of manufacturing a semiconductor package including: disposing prepreg for forming a prepreg layer on a substrate having an element mounted thereon; disposing a sheet forming a metal shielding layer on an upper portion of the prepreg; forming a prepreg layer and a metal shielding layer by pressing the prepreg and the sheet; and forming a plurality of via electrodes along edges of the prepreg layer and the metal shielding layer.

The method may further include cutting the prepreg layer, the metal shielding layer, and the substrate such that the plurality of via electrodes are disposed therein.

The plurality of via electrodes may be spaced apart from each other along the edges of the prepreg layer and the metal shielding layer.

The prepreg and the sheet may be pressed by press forming.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view illustrating a semiconductor package according to an exemplary embodiment of the present invention;

FIG. 2 is a schematic cross sectional view illustrating the semiconductor package according to the exemplary embodiment of the present invention;

FIG. 3 is a plan view illustrating the semiconductor package according to the exemplary embodiment of the present invention; and

FIGS. 4A to 4E are flow charts illustrating a process of manufacturing a semiconductor package according to an exemplary embodiment of the present invention.

### DETAILED DESCRIPTION OF THE INVENTION

Embodiments of the present invention will now be described in detail with reference to the accompanying drawings. However, it should be noted that the spirit of the present invention is not limited to the embodiments set forth herein and those skilled in the art and understanding the present invention can easily accomplish retrogressive inventions or other embodiments included in the spirit of the present invention by the addition, modification, and removal of components within the same spirit, but those are construed as being included in the spirit of the present invention.

Further, when it is determined that the detailed description of the known art related to the present invention may obscure the gist of the present invention, the detailed description thereof will be omitted.

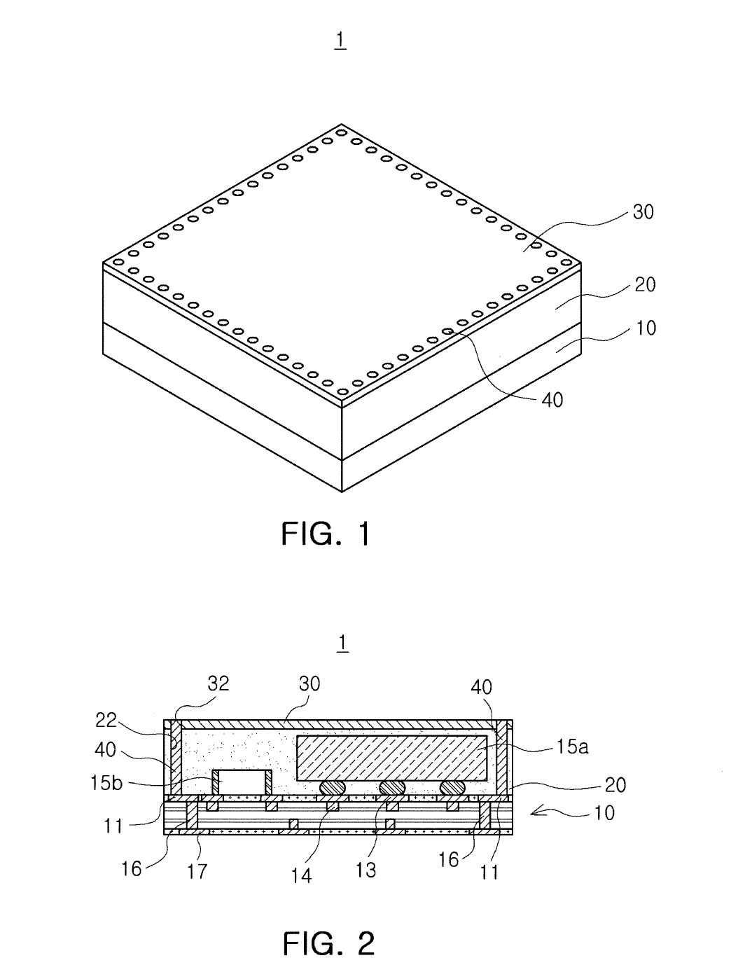

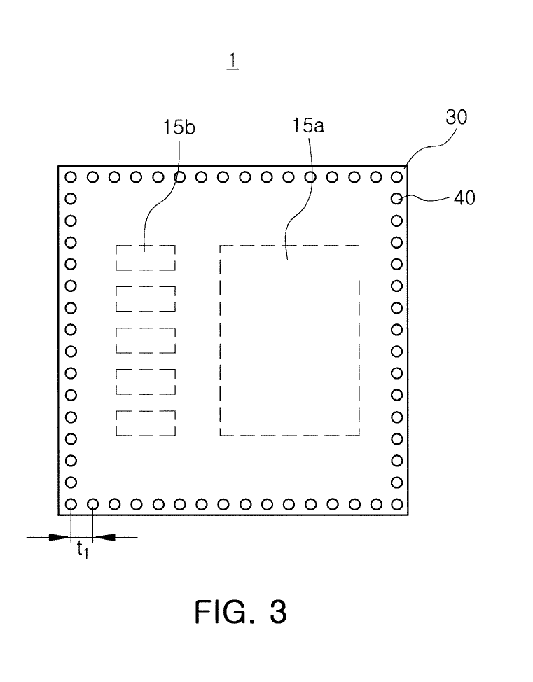

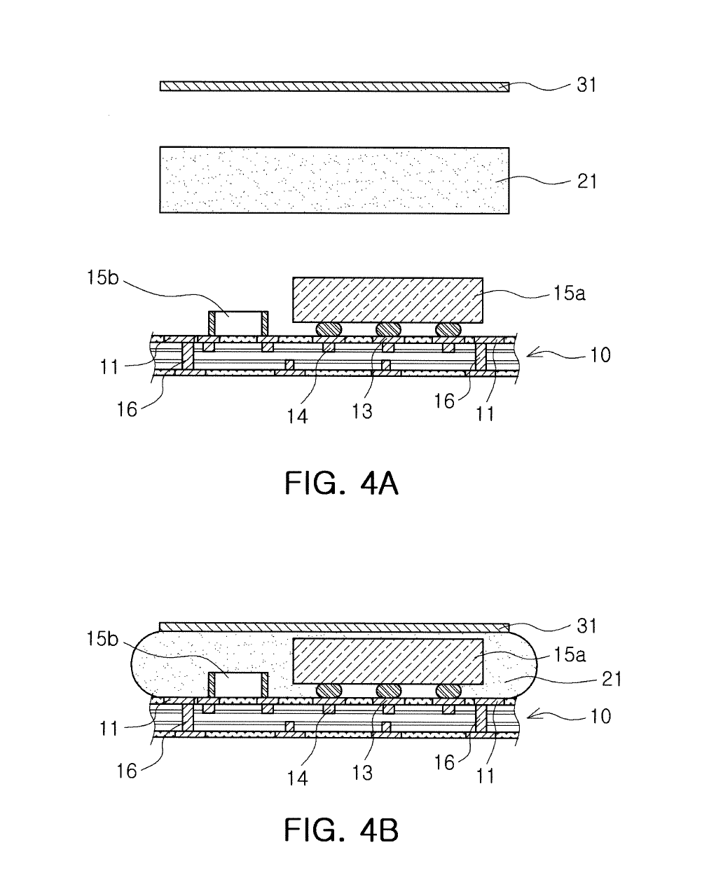

FIG. 1 is a perspective view illustrating a semiconductor package according to an exemplary embodiment of the present invention, FIG. 2 is a schematic cross sectional view illustrating the semiconductor package according to the exemplary embodiment of the present invention, and FIG. 3 is a plane view illustrating the semiconductor package according to the exemplary embodiment of the present invention.

Referring to FIGS. 1 to 3, a semiconductor package 1 according to an exemplary embodiment of the present invention includes a substrate 10, a prepreg layer 20, a metal shielding layer 30, and a via electrode 40.

One or more elements 15a and 15b may be mounted on the substrate 10. As the substrate 10, various types of substrate well known in the related art (for example, a ceramic substrate, a printed circuit board (PCB), a flexible substrate or etc.) may be used.

On a top surface of the substrate 10, wiring electrodes 13, which are to mount the elements 15a and 15b on the top surface of the substrate 10, or wiring patterns 14, which are to electrically connect the wiring electrodes 13 with each other, may be formed.

The substrate 10 may be a multilayer substrate that includes a plurality of layers. In this case, a circuit pattern (not shown) may be formed between the layers to form electrical connection.

Also, a ground electrode 11 may be formed on the top surface of the substrate 10. The ground electrode 11 may be formed along a side on the top surface of the substrate 10, which is formed to have a quadrangular shape.

The ground electrode 11 may be formed along at least one of four sides of the substrate 10. That is, the ground electrode 11 may be formed along both sides of the substrate 10 on the top surface of the substrate 10 or may be formed along the four sides of the substrate 10.

If the ground electrode 11 is formed along the four sides of the substrate 10, the ground electrode 11 is formed to have a quadrangular shape along an exterior of the substrate 10.

Also, the ground electrode 11 may be formed along the side of the substrate 10 while having a predetermined width. In a case in which the ground electrode 11 needs to be electrically connected to terminals of the elements 15a and 15b, the ground electrode 11 may be formed in such a manner that a part of the ground electrode 11 protrudes downwardly of the elements 15a and 15b and thus, the protruding part is electrically connected to the terminals (that is, ground terminals) of the elements 15a and 15b.

In addition, the ground electrode 11 may be provided in plural. For example, the ground electrode 11 may include two ground electrodes, and the respective two ground electrodes 11 may be formed on opposite sides of the substrate 10 and have the same width. If necessary, the ground electrodes 11 may be variously formed, such as having different widths.

A ground via 16 may be formed in the substrate 10 to electrically connect the ground electrode 11 and an external connection terminal 17.

The elements 15a and 15b mounted on the substrate 10 may include various electronic elements such as a passive element and an active element, and any element may be used as the elements 15a and 15b, as long as it may be mounted on the substrate 10 or embedded in the substrate 10.

The prepreg layer 20 may be stacked on the substrate 10 so as to cover the elements 15a and 15b. That is, the prepreg layer 20 may be stacked on the substrate 10 to accommodate the elements 15a and 15b mounted on the substrate 10 therein.

The prepreg layer 20 may be formed by disposing prepreg on the substrate 10 and pressing the disposed prepreg. That is, the prepreg may be an insulating material manufactured by impregnating a glass fiber substance such as glass cloth with a thermosetting resin such as epoxy resin or the like, and the prepreg layer 20 may be formed by heating, pressing, and hardening the stacked prepreg.

The prepreg layer 20 made of the above described prepreg may improve moisture resistance.

If external impacts are applied to the prepreg layer 20, the prepreg layer 20 may perform a function of protecting the elements 15a and 15b mounted on the substrate 10.

Also, a penetrating hole 22 may be formed in the prepreg layer 20 such that the via electrode 40 may be formed therein. The penetrating hole 22 may extend from a top surface of the prepreg layer 20 to a bottom surface thereof.

The metal shielding layer 30 is stacked on the prepreg layer 20 to electrically shield the elements 15a and 15b. The metal shielding layer 30 may include a copper sheet made of copper.

Also, the metal shielding layer 30 may be formed along with the prepreg layer 20 when the prepreg layer 20 is formed. That is, the prepreg layer 20 and the metal shielding layer 30 may be formed by disposing a copper sheet on the top surface of the prepreg disposed on the substrate 10 and then pressing the prepreg and the copper sheet.

A communication hole 32 may be formed in the metal shielding layer 30 so as to be connected to the penetrating hole 22 formed in the prepreg layer 20. That is, the penetrating hole 22 of the prepreg layer 20 and the communication hole 32 of the metal shielding layer 30 may be integrally formed with each other after the prepreg layer 20 and the metal shielding layer 30 are formed.

However, the metal shielding layer 30 is not limited to the forming method as described above and the metal shielding layer 30 may be stacked on the prepreg layer 20 by various ways, such as sputtering, vapor-deposition, spray coating, screen printing, electroplating and electroless plating.

Although not shown, a protective layer such as a solder resist or the like may be further formed on an upper portion of the metal shielding layer 30, if necessary.

The via electrode 40 may penetrate through the metal shielding layer 30 and the prepreg layer 20 and be electrically connected to the ground electrode 11 formed on the substrate 10. That is, the via electrode 40 is formed in the penetrating hole 22 of the prepreg layer 20 and the communication hole 32 of the metal shielding layer 30, so that one side of the via electrode 40 may contact the ground electrode 11.

The via electrode 40 may be provided in plural and the plurality of via electrodes 40 may be space apart from each other along edges of the prepreg layer 20 and the metal shielding layer 30. In other words, the plurality of via electrodes 40 may be formed adjacent to side surfaces of the prepreg layer 20 and the metal shielding layer 30.

The respective via electrodes 40 may have a gap t1 therebetween as below (a gap between adjacent via electrodes 40).

For example, if a frequency of 10 GHz is used, the gap t1 between the adjacent via electrodes 40 may be 0.75 mm in order to block electromagnetic waves.

More specifically, if the frequency of 10 GHz is used, a wavelength (λ) may be 30 mm. That is, λ=C/f, where, C is a luminous flux and f is 10 GHz.

Accordingly, the wavelength (λ) is 30 mm.

When it is assumed that a dielectric constant of a PCB is 4, an effective wavelength (λ′) is 15 mm. That is, since λ′=λ/Sqrt(4), the effective wavelength (λ′) is 15 mm.

For example, when first to twentieth high frequencies are considered among harmonic components of a fundamental wave to block the electromagnetic waves from the 10 GHz frequency, the gap t1 between the adjacent via electrodes 40 may be 0.75 mm. That is, since t1=λ′/20, t1 may be 0.75 mm.

However, the gap t1 between the adjacent via electrodes 40 is not limited to 0.75 mm. That is, the gap t1 between the adjacent via electrodes 40 may be changed according to the magnitude of the frequency, the dielectric constant of the PCB, and n^{th} high frequencies considered among the harmonic components.

As another example, if a frequency of 20 GHz is used, the gap t1 between the adjacent via electrodes 40 may be 0.375 mm in order to block the electromagnetic waves.

More specifically, if the frequency of 20 GHz is used, the wavelength (λ) may be 15 mm. That is, λ=C/f, where, C is a luminous flux and f is 20 GHz.

Accordingly, the wavelength (λ) is 15 mm.

When it is assumed that the dielectric constant of the PCB is 4, the effective wavelength (λ′) is 7.5 mm. That is, since λ′=λ/Sqrt(4), the effective wavelength (λ′) is 7.5 mm.

When first to twentieth high frequencies are considered among harmonic components of a fundamental wave to block the electromagnetic waves from the 20 GHz frequency, the gap t1 between the adjacent via electrodes 40 may be 0.375 mm. That is, since t1=λ′/20, t1 may be 0.375 mm.

As described above, by adjusting the gap t1 between the adjacent via electrodes 40, leakage of the electromagnetic wave can be more reduced.

In this embodiment, the respective via electrodes 40 may have a circular cylinder shape. However, the shape of the via electrodes 40 is not limited thereto and the respective via electrodes 40 may have a polygonal prism shape such as a rectangular prism shape or the like.

As described above, the semiconductor package according to the embodiment of the present invention may realize the slimming thereof and obtain improved moisture resistance through the prepreg layer 20 and the metal shielding layer 30.

That is, an electromagnetic wave shielding structure including the prepreg layer 20 and the metal shielding layer 30 may be formed, whereby the semiconductor package may realize the slimming thereof, as compared to the case having an electromagnetic wave shielding structure including a cover member made of a metal material.

In addition, the electromagnetic wave shielding structure including the prepreg layer 20 and the metal shielding layer 30 may improve the moisture resistance, as compared to an electromagnetic wave shielding structure manufactured by covering a thin conductive film after the performing of packaging using a molding product.

In other words, since a material of prepreg 21 is more resistant against moisture as compared to a molding material, moisture resistance thereof may be improved.

Hereinafter, a method of manufacturing a semiconductor package according to an exemplary embodiment will be explained with reference to the accompanying drawings.

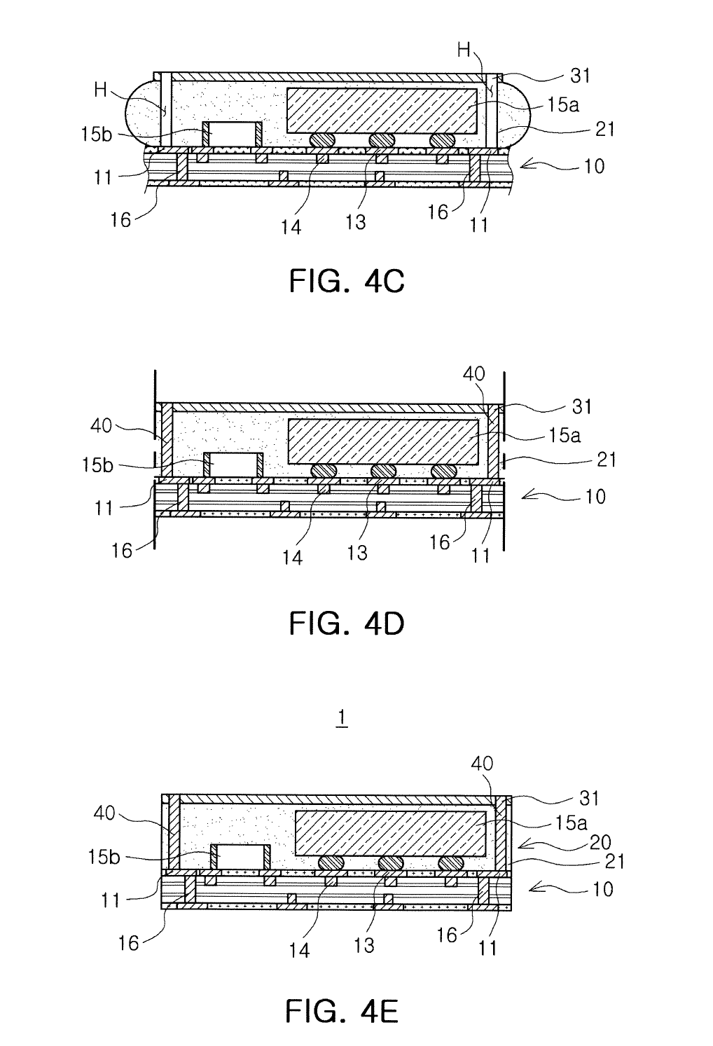

FIGS. 4A to 4E are flow charts illustrating a process of manufacturing a semiconductor package according to an exemplary embodiment of the present invention.

Referring to FIG. 4A, the substrate 10 on which the one or more elements 15a and 15b are mounted, the prepreg 21 and a sheet 31 are prepared.

On the top surface of the substrate 10, the wiring electrodes 13, which are to mount the elements 15a and 15b on the top surface of the substrate 10, or the wiring patterns 14, which are to electrically connect the wiring electrodes 13 with each other, may be formed.

Also, the substrate 10 may be a multilayer substrate which includes a plurality of layers, and a circuit pattern (not shown) may be formed between the layers to form electrical connection.

Also, the ground electrode 11 may be formed on the top surface of the substrate 10. The ground electrode 11 may be extended along a side of the substrate 10 while having a predetermined width. In a case in which the ground electrode 11 needs to be electrically connected to terminals of the elements 15a and 15b, the ground electrode 11 may be formed in such a manner that a part of the ground electrode 11 protrudes downwardly of the elements 15a and 15b and thus, the protruding part is electrically connected to the terminals (that is, ground terminals) of the elements 15a and 15b.

The ground via 16 may be formed in the substrate 10 to electrically connect the ground electrode 11 and an external connection terminal 17.

The elements 15a and 15b mounted on the substrate 10 may include various electronic elements such as a passive element and an active element, and any element may be used as the elements 15a and 15b, as long as it may be mounted on the substrate 10 or embedded in the substrate 10.

Thereafter, as shown in FIG. 4B, the prepreg 21 forming a prepreg layer 20 (see FIG. 4F) is disposed on the substrate 10 having the elements 15a and 15b mounted thereon. That is, the prepreg 21 may be stacked on the substrate 10 to accommodate the elements 15a and 15b mounted on the substrate 10 therein.

Thereafter, the sheet 31 forming the metal shielding layer 30 may be disposed on the upper portion of the prepreg 21. The sheet 31 may be a copper sheet.

Thereafter, the prepreg layer 20 and the metal shielding layer 30 may be formed by pressing the prepreg 21 and the sheet 31 using a press. In other words, the prepreg layer 20 and the metal shielding layer 30 are stacked on the substrate 10 by simultaneously pressing the prepreg 21 and the sheet 31 disposed on the substrate 10.

Accordingly, the prepreg layer 20 and the metal shielding layer 30 are formed.

Thereafter, as shown in FIG. 4C, the penetrating hole 22 and the communication hole 32 are simultaneously formed in the prepreg layer 20 and the metal shielding layer 30 to form the plurality of via electrodes 40 (see FIG. 4D).

That is, the penetrating hole 22 and the communication hole 32 are integrally formed with each other in the prepreg layer 20 and the metal shielding layer 30 stacked on the substrate 10.

In this case, the penetrating hole 22 is formed in the prepreg layer 20 in such a manner that the ground electrode 11 is disposed under the penetrating hole 22.

Thereafter, as shown in FIG. 4D, the via electrodes 40 made of a conductive material are formed in the penetrating hole 22 and the communication hole 32.

In other words, each via electrodes 40 penetrates through the metal shielding layer 30 and the prepreg layer 20 and is electrically connected to the ground electrode 11 formed on the substrate 10. That is, the via electrode 40 is formed in the penetrating hole 22 of the prepreg layer 20 and the communication hole 32 of the metal shielding layer 30, such that one side of the via electrode 40 contacts the ground electrode 11.

Also, the plurality of via electrodes 40 may be spaced apart from each other along edges of the prepreg layer 20 and the metal shielding layer 30. In other words, the plurality of via electrodes 40 may be formed adjacent to side surfaces of the prepreg layer 20 and the metal shielding layer 30.

The adjacent via electrodes 40 may have the gap t1 therebetween as below.

For example, if a frequency of 10 GHz is used, the gap t1 between the adjacent via electrodes 40 may be 0.75 mm in order to block electromagnetic waves.

More specifically, if the frequency of 10 GHz is used, a wavelength (λ) may be 30 mm. That is, λ=C/f, where, C is a luminous flux and f is 10 GHz.

Accordingly, the wavelength (λ) is 30 mm.

When it is assumed that a dielectric constant of a PCB is 4, an effective wavelength (λ′) is 15 mm. That is, since λ′=λ/Sqrt(4), the effective wavelength (λ′) is 15 mm.

For example, when first to twentieth high frequencies are considered among harmonic components of a fundamental wave to block the electromagnetic waves from the 10 GHz frequency, the gap t1 between the adjacent via electrodes 40 may be 0.75 mm. That is, since t1=λ′/20, t1 may be 0.75 mm.

However, the gap t1 between the adjacent via electrodes 40 is not limited to 0.75 mm. That is, the gap t1 between the adjacent via electrodes 40 may be changed according to the magnitude of the frequency, the dielectric constant of the PCB, and n^{th} high frequencies considered among the harmonic components.

As another example, if a frequency of 20 GHz is used, the gap t1 between the adjacent via electrodes 40 may be 0.375 mm in order to block the electromagnetic waves.

More specifically, if the frequency of 20 GHz is used, the wavelength (λ) may be 15 mm. That is, λ=C/f, where, C is a luminous flux and f is 20 GHz.

Accordingly, the wavelength (λ) is 15 mm.

When it is assumed that the dielectric constant of the PCB is 4, the effective wavelength (λ′) is 7.5 mm. That is, since λ′=λ/Sqrt(4), the effective wavelength (λ′) is 7.5 mm.

When first to twentieth high frequencies are considered among harmonic components of a fundamental wave to block the electromagnetic waves from the 20 GHz frequency, the gap t1 between the adjacent via electrodes 40 may be 0.375 mm. That is, since t1=λ′/20, t1 may be 0.375 mm.

As described above, by adjusting the gap t1 between the adjacent via electrodes 40, leakage of the electromagnetic wave can be more reduced.

In this embodiment, the respective via electrodes 40 may have a circular cylinder shape. However, the shape of the via electrodes 40 is not limited thereto and the respective via electrodes 40 may have a polygonal pillar shape such as a rectangular pillar shape or the like.

Thereafter, as shown in FIG. 4D, the prepreg layer 20, the metal shielding layer 30, and the substrate 10 are cut in such a manner that the via electrodes 40 are disposed therein. In other words, as shown in FIG. 4D, the prepreg layer 20, the metal shielding layer 30, and the substrate 10 are cut along a cutting line in such a manner that the via electrodes 40 are disposed inside the prepreg layer 20 and the metal shielding layer 30 so as not to be exposed to the outside.

When a cutting process is completed as described above, the semiconductor package 1 is provided as shown in FIG. 4E.

As described above, the electromagnetic wave shielding structure including the prepreg layer 20 and the metal shielding layer 30 may be formed, whereby the semiconductor package may realize the slimming thereof, as compared to the case having an electromagnetic wave shielding structure including a cover member made of a metal material.

In addition, the electromagnetic wave shielding structure including the prepreg layer 20 and the metal shielding layer 30 may improve moisture resistance, as compared to an electromagnetic wave shielding structure manufactured by covering a thin conductive film after the performing of packaging using a molding product.

In other words, since a material of the prepreg 21 is more resistant against moisture as compared to a molding material, moisture resistance thereof may be improved.

Also, since the via electrodes 40 are disposed inside the prepreg layer 20 and the metal shielding layer 30, that is, since the via electrodes 40 are not exposed to the outside of the prepreg layer 20 and the metal shielding layer 30, leakage of the electromagnetic wave may be more suppressed.

As set forth above, according to the exemplary embodiments of the present invention, the semiconductor package may realize the sliming thereof, while having improved moisture resistance through the use of the prepreg layer and the metal shielding layer.

While the present invention has been shown and described in connection with the exemplary embodiments, it will be apparent to those skilled in the art that modifications and variations can be made without departing from the spirit and scope of the invention as defined by the appended claims.

What is claimed is:

1. A semiconductor package comprising:
a substrate having at least one element mounted thereon;
a prepreg layer stacked on the substrate to cover the at least one element;
a metal shielding layer stacked on the prepreg layer to electrically shield the at least one element; and
a via electrode penetrating through the metal shielding layer and the prepreg layer and electrically connected to a ground electrode formed on the substrate.

2. The semiconductor package of claim 1, wherein the via electrode includes a plurality of via electrodes, and the plurality of via electrodes are spaced apart from each other along edges of the prepreg layer and the metal shielding layer.

3. A method of manufacturing a semiconductor package comprising:
disposing prepreg for forming a prepreg layer on a substrate having an element mounted thereon;
disposing a sheet forming a metal shielding layer on an upper portion of the prepreg;
forming a prepreg layer and a metal shielding layer by pressing the prepreg and the sheet; and
forming a plurality of via electrodes along edges of the prepreg layer and the metal shielding layer.

4. The method of claim 3, further comprising cutting the prepreg layer, the metal shielding layer, and the substrate such that the plurality of via electrodes are disposed therein.

5. The method of claim 4, wherein the plurality of via electrodes are spaced apart from each other along the edges of the prepreg layer and the metal shielding layer.

6. The method of claim 4, wherein the prepreg and the sheet are pressed by press forming.
